(19) United States
(12) Patent Application Publication
(10) Pub. No.: US 2012/0168713 A1
(43) Pub. Date: Jul. 5, 2012

(54) METHOD FOR MANUFACTURING A SILICON NANOWIRE ARRAY USING A POROUS METAL FILM

(75) Inventors: Woo Lee, Daejeon (KR); Jung-Kil Kim, Yongin-si (KR); Jae-Cheon Kim, Daejeon (KR)

(73) Assignee: Korea Research Institute of Standards and Science, Daejeon (KR)

(21) Appl. No.: 13/394,093

(22) PCT Filed: Sep. 3, 2010
(86) PCT No.: PCT/KR2010/005990

§ 371 Date: Mar. 2, 2012

(30) Foreign Application Priority Data
Sep. 3, 2009 (KR) 10-2009-0083072
Aug. 23, 2010 (KR) 10-2009-0081366

(51) Int. Cl. H01L 29/12; H01L 21/326; B82Y 99/00; B82Y 40/00

(52) U.S. Cl. 257/9; 438/466; 977/762; 977/840; 257/E29.068; 257/E21.327

(57) ABSTRACT

The present invention is to provide a method for manufacturing a silicon nanowire array comprising (a) preparing a porous metal film; (b) placing the porous metal film in contact with a silicon substrate; and (c) etching the silicon substrate with a silicon etching solution. The present invention allows manufacturing vertically aligned large-area silicon nanowires by using the porous metal film as a catalyst and manufacturing nanowires having a porous structure, a porous nodular structure, an inclined structure and a zig-zag structure, which are distinguishable from nanowires of the prior art in their shape and crystallographic orientation, by adjusting etching conditions such as the composition of the silicon etching solution and the etching temperature in the step in which the silicon substrate is subjected to wet etching.

### TECHNICAL FIELD

The present invention relates to a method for manufacturing a silicon nanowire array using a porous metal film and a silicon nanowire array manufactured thereby. More particularly, it relates to a method for manufacturing a silicon nanowire array using a porous metal film as a catalyst through a selective etching process, and silicon nanowires with distinguishable shape and crystallographic orientation manufactured thereby,

### BACKGROUND

A great deal of development research is currently under way on applying silicon nanowires to light-small-short-thin optoelectronic devices, memory devices, biological sensors, energy devices and the like with high performance. It is important not only to control diameter and length of silicon nanowires uniformly but also to have an array uniformly controlled on exact locations in order to be used as a practical device in manufacturing silicon icon nanowires. It is essential for devices such as a field-effect transistor(FET) to have spatially well aligned silicon nanowires and have ability to control their density and many studies have been performed to manufacture a vertically aligned silicon nanowire array.

When a silicon nanowire is prepared by a bottom-up method, represented as a Vapor-liquid-solid(VLS) growth mechanism, diameter and density of a single crystal silicon nanowire can be controlled by adjusting metal catalyst particles. However, it is difficult to control diameter and location of nanowires if diameters of nanoparticles are not completely uniform nor electron beam lithography is used. Further, because silicon nanowires have a propensity to grow to a specific direction depending on the diameter of metal catalyst particles, it cannot be compatible with a conventional CMOS process primarily using silicon wafer.

A cost effective top-down method for manufacturing silicon nanowires includes a chemical wet etching method using a metal as a catalyst. This method is able to control somewhat for diameter, length and density of silicon nanowires using a polymer nanosphere lithography. This method is also economical and allows high productivity compared to a conventional lithography method because it patterns a metal film using a polymer nanosphere mask having hexagonal arrays formed on a silicon substrate and selectively wet etches the silicon surface in contact with a metal to obtain silicon nanowires. However, there is limit to manufacture large-area aligned polymer nanosphere masks without defects and uniform silicon nanowire arrays having a diameter of 50 nm or less due to polymer sphere size limit.

Recently, an economic method has been used for manufacturing a silicon nanowire array having a diameter of 10 nm or less, which includes placing a nanoporous alumina mask in the form of a thin film on a silicon substrate, forming mask patterns on the silicon substrate through a reactive ion etching(RIE), depositing a metal on the silicon substrate on which the patterns are formed to provide a metal film in the form of a mesh, and using the metal film as a catalyst for a chemical wet etching. However, some drawbacks to this method are that a process to obtain a nanoporous alumina mask is cumbersome, and since a ceramic mask placed on the silicon substrate has a lot of folds having a size of several micrometers, mask patterns at the folded area cannot be formed on the silicon substrate nor form silicon nanowires during the etching process. In addition, because a metal can be deposited on grooves etched by an ion beam during the deposition of a metal on a silicon substrate on which patterns are formed, the upper part of the silicon nanowires obtained by a chemical etching may be very uneven.

There is another method for manufacturing a silicon nanowire array as a modification of the above method, which includes depositing a metal directly to a nanoporous alumina mask placed on a silicon substrate and immersing it to an etching solution. However, this method also has drawbacks such that a metal film can be separated out from the silicon substrate which is, therefore, not suitable for manufacturing large-are uniform silicon nanowire arrays.

A cost effective top-down method, which is a representative method for manufacturing silicon nanowires, is a chemical wet etching of a silicon substrate using a metal as a catalyst. Here, the catalyst can be Au, Pt or Ag.

In addition, various applications of porous silicon nanowires such as optoelectronic devices, memory devices, high efficiency lithium batteries, solar cells and the like have been studied by developing silicon nanowires having a porous structure which thus have unique optical properties. In previous studies, there is disadvantage to use a certain type or a certain level of high doped silicon substrate in order to manufacture porous silicon nanowires by a cost effective top-down method.

A conventional cost effective top-down method for manufacturing silicon nanowires cannot provide silicon nanowires having 2 or more crystallographic orientations by using one substrate and is also difficult to provide nanowires having a uniform diameter and a single crystal structure within a short period of time at the same time.

### DISCLOSURE

### Technical Problem

The present invention is to provide a method for manufacturing a porous single layered metal film which allows controlling an opening shape and low manufacturing cost, a method for manufacturing a vertically aligned uniform nanowire array over a large-area by overcoming several technical limits associated with a conventional method for manufacturing a silicon nanowire array through a chemical wet etching of a silicon substrate using a metal as a catalyst, and a method for quickly etching a silicon substrate maintaining stable structure and using properties of metals in each layer by preparing an ordered porous multi-layered metal film.

Further, the present invention is to provide a method for manufacturing a silicon nanowire array having various crystallographic orientations on one silicon substrate by controlling an etching direction in which it overcomes the limitation of manufacturing a silicon nanowire array having only one crystallographic orientation on one silicon substrate, a method for manufacturing a silicon nanowire array having a zig-zag structure which is formed by twisting crystallographic orientations of two different directions in constant intervals, a method for manufacturing a porous silicon nanowire array implementable on various substrates and a method for manufacturing a silicon nanowire array having a porous nodular structure.

### Technical Solution

According to an aspect of the present invention, there is provided a method for manufacturing a silicon nanowire array comprising (a) preparing a porous metal flim; (b) placing the porous metal film in contact with a silicon substrate; and (c) etching the silicon substrate with a silicon etching solution.

According to an embodiment of the present invention, the step (a) of preparing a porous metal film comprises: providing a template having a polarity of holes on one side; depositing a metal on one side of the template; and etching only the template with a template etching solution.

According to an embodiment of the present invention, the porous metal film may be formed with a multilayer of 2 or more layers composed of different metals.

According to an embodiment of the present invention, the cross section of the hole of the one side of the template may have shape selected from the group consisting of round, oval, square, rectangular and regular polygon.

According to an embodiment of the present invention, a material of the template is alumina and the hole of the one side of the template may be formed by an anodizing method.

According to an embodiment of the present invention, the method may further comprises polishing the surface of the porous metal film to make the surface of the porous metal film be smooth after only etching the template.

According to an embodiment of the present invention, the step of placing the porous metal film in contact with a silicon substrate may comprise floating the porous metal film on the surface of a carrier solution; placing one side of the porous metal film in contact with the surface of the carrier solution to contact with the silicon substrate; and evaporating the carrier solution remained on the silicon substrate.

According to an embodiment of the present invention, the carrier solution is the silicon etching solution and the step of evaporating the carrier solution remained on the silicon substrate may etch a part of the silicon substrate with the carrier solution at the area in contact with the porous metal film and adhere the porous metal film and the silicon substrate.

According to an embodiment of the present invention, the carrier solution is deionized water and the method may further comprise immersing the silicon substrate in contact with the porous metal film in an anhydrous ethanol(C₂H₅OH) after the step of evaporating the carrier solution remained on the silicon substrate.

According to an embodiment of the present invention, the porous the metal film acts as a catalyst in the silicon etching solution to form nanowires by a wet etching method at the step of (c),

According to an embodiment of the present invention, the silicon etching solution may be a mixture of HF, H₂O₂ and H₂O or a mixture of NH₄F, H₂O₂ and H₂O.

According to an embodiment of the present invention, the silicon etching solution may be a mixture of HF, H₂O₂ and H₂O having a volume ratio of HF:H₂O₂:H₂— 1:x:2(wherein x is 0.5 or higher) to form the silicon nanowires having a porous structure in the step of (c).

According to an embodiment of the present invention, the silicon etching solution may be a mixture of HF, H₂O₂ and H₂O and after etching with the mixture of HF, H₂O₂ and H₂O as the silicon etching solution in the step of (c), an additional etching is performed with a mixture having a lowered concentration of HF in the mixture to form the silicon nanowires having a porous nodular structure.

According to an embodiment of the present invention, in the step of (c), when a voltage is applied to the silicon substrate, the area of the silicon nanowires where the voltage is applied may have a porous structure to form silicon nanowires having a porous nodular structure.

According to an embodiment of the present invention, in the step of (c), axes of the silicon nanowires may form an inclined structure against the surface of the substrate by using a heated silicon etching solution.

According to an embodiment of the present invention, in the step of (c), silicon nanowires having a zig-zag structure may be formed by alternately etching with the silicon etching solution having different concentrations of H₂O₂.

According to another aspect of the present invention, there is provided a silicon nanowire array manufactured according to the method above.

According to further another aspect of the present invention, there is provided a semiconductor device including the silicon nanowire array.

### Advantageous Effects

The present invention allows manufacturing a porous metal film with uniform opening parts and low manufacturing cost, transferring without defects only to areas other than where nanowires are to be formed on a silicon substrate, overcoming drawbacks such as uneven silicon etching, several micro defective areas where nanowires are not formed and the like, associated with a conventional chemical wet etching of silicon using a metal as a catalyst, and manufacturing vertically aligned uniform silicon nanowires on a large-area substrate regardless of substrate areas and crystallographic orientations.

Further, the present invention allows manufacturing a silicon nanowire array having one or more crystallographic orientations by controlling etching directions of silicon nanowires manufactured on a silicon substrate having one crystallographic orientation by preparing not only an ordered porous single layered metal film but also an ordered porous multilayered metal film and utilizing properties of the metal in each layer and also allows manufacturing a silicon nanowire array having an inclined structure, in which axes of the nanowires are inclined against the substrate, and a silicon nanowire array having a zig-zag structure crossed with one or more crystallographic orientations in constant intervals.

Still further, the present invention allows manufacturing a silicon nanowire array having desired surface roughness and morphology controlled only by etching conditions, regardless of crystallographic orientations, doping types and doping levels of a substrate.

### BRIEF DESCRIPTION OF DRAWINGS

FIG. 1 is a schematic view illustrating manufacturing a silicon nanowire array controlled with shapes and crystallographic orientations.

FIG. 2 is a flowchart illustrating a method for manufacturing a silicon nanowire array.

FIG. 3 is a flowchart illustrating a method for manufacturing a porous metal film.

FIG. 4 is a sectional view illustrating a template on which a metal is deposited.

FIG. 5 is a sectional view illustrating the state that a template is separated from a porous metal film in a method for manufacturing the porous metal film.

FIG. 6 is a sectional view illustrating the state after polishing the surface of a porous metal film in a method for manufacturing the porous metal film.

FIG. 7 is a SEM image illustrating an embodiment of a porous single layered metal film manufactured by a method for manufacturing a porous metal film.

FIG. 8 is a SEM image illustrating an embodiment of a porous multilayered metal film manufactured by a method for manufacturing a porous metal film.

FIG. 9 is a sectional view illustrating the step of floating a porous metal film on a carrier solution in a method for manufacturing a silicon nanowire array.

FIG. 10 is a sectional view illustrating the step of moving a porous metal film on a silicon substrate in a method for manufacturing a silicon nanowire array.

FIG. 11 is a sectional view illustrating the state that a porous metal film is moved on a silicon substrate in a method for manufacturing a silicon nanowire array.

FIG. 12 is a sectional view illustrating the state that the e silicon substrate on which a porous metal film is moved is dried in a method for manufacturing a silicon nanowire array.

FIG. 13 is a perceptive view illustrating the state that the silicon substrate on which a porous metal film is moved is dried in a method for manufacturing a silicon nanowire array.

FIG. 14 is a sectional view illustrating the step of etching a silicon substrate with a porous metal film as a catalyst in a method for manufacturing a silicon nanowire array.

FIG. 15 is a sectional and perceptive view illustrating a vertically aligned silicon nanowire array manufactured by a method for manufacturing a silicon nanowire array.

FIGS. 16 and 17 are SEM images each illustrating en embodiment of a silicon nanowire array manufactured by using a porous single layered metal film in a method for manufacturing a silicon nanowire array.

FIG. 18 is a SEM image illustrating en embodiment of a silicon nanowire array manufactured by etching a silicon substrate with a porous multilayered metal film as a catalyst in a method for manufacturing a silicon nanowire array.

FIG. 19 is a sectional view illustrating a silicon nanowire array having a porous structure manufactured by using a porous metal film in a method for manufacturing a silicon nanowire array.

FIG. 20 is a sectional view illustrating a silicon nanowire array having a porous nodular structure manufactured by using a porous metal film in a method for manufacturing a silicon nanowire array.

FIG. 21 is a sectional view illustrating a silicon nanowire array having an inclined structure in which axes of nanowires are inclined against the substrate manufactured by using a porous metal film are inclined against a substrate film in a method for manufacturing a silicon nanowire array.

FIG. 22 is a sectional view illustrating a silicon nanowire array having a zig-zag structure manufactured by using a porous metal film in a method for manufacturing a silicon nanowire array.

FIG. 23 is a SEM image illustrating an embodiment of a silicon nanowire array having a porous structure manufactured by using a porous metal film in a method for manufacturing a silicon nanowire array.

FIG. 24 is a SEM image illustrating an embodiment of a silicon nanowire array having a porous nodular structure manufactured by using a porous metal film in a method for manufacturing a silicon nanowire array.

FIG. 25(a) and FIG. 25(b) are SEM images each illustrating an embodiment of a silicon nanowire array having a different shape and crystallographic orientation manufactured by adjusting etching conditions such as composition of a silicon etching solution or etching temperature according to another aspect of the present invention.

FIG. 26 is a SEM image illustrating an embodiment of a silicon nanowire array having a zig-zag structure manufactured by using a porous metal film in a method for manufacturing a silicon nanowire array.

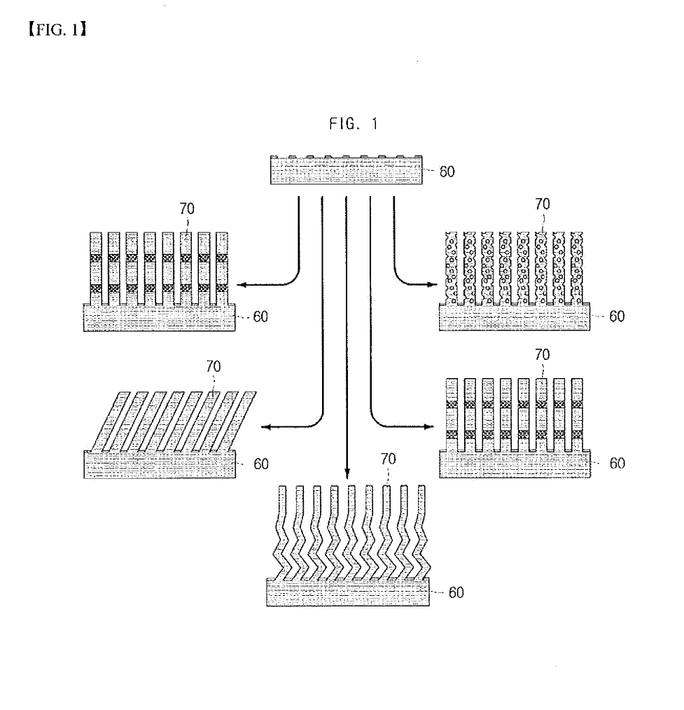

### DESCRIPTION OF REFERENCE NUMERALS

10: holes formed on a template

30: template

40: porous metal film

50: opening part of a porous metal film

60: silicon substrate

70: nanowires

80: carrier solution

### MODE FOR INVENTION

While the present invention has been described with reference to particular embodiments, it is to be appreciated that various changes and modifications may be made by those skilled in the art without departing from the spirit and scope of the present invention, as defined by the appended claims and their equivalents. Throughout the description of the present invention, when describing a certain technology is determined to evade the point of the present invention, the pertinent detailed description will be omitted

While such terms as “first” and “second,” etc., may be used to describe various components, such components must not be limited to the above terms. The above terms are used only to distinguish one component from another.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

The present invention will be described below in more detail with reference to the accompanying drawings, in which those components are rendered the same reference number that are the same or are in correspondence, regardless of the figure number, and redundant explanations are omitted.

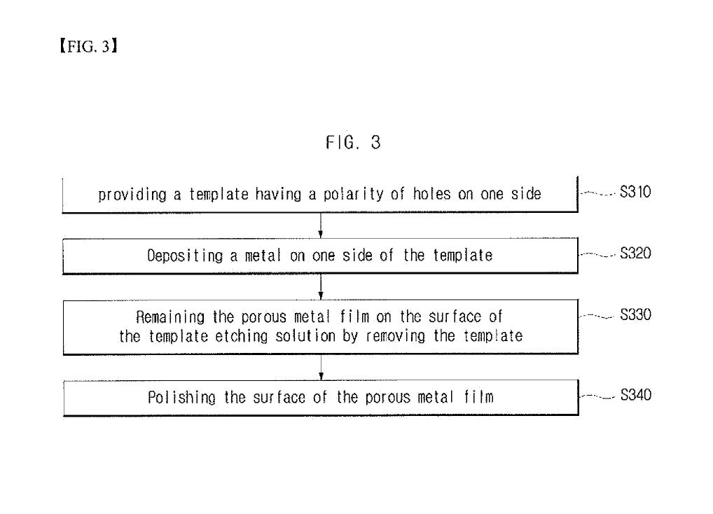

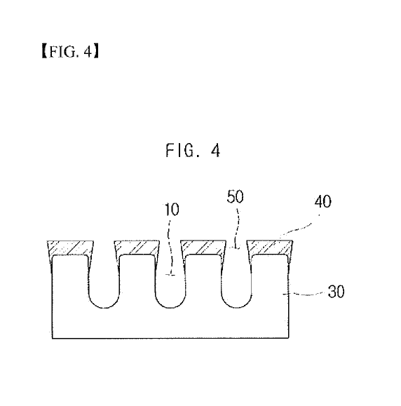

FIG. 3 is a flowchart illustrating a method for manufacturing a porous metal film, and FIG. 4 to FIG. 6 are sectional views illustrating a method for manufacturing a porous metal film according to an embodiment of the present invention. Referring to FIG. 4 to FIG. 6, they illustrate holes 10 formed on a template, template 30, porous metal film 40 and opening parts 50 formed on the porous metal film 40.

The porous metal film 40 may be a thin film of a metal material having a plurality of opening parts 50, suitable as a patterning mask of various substrates, and act as a catalyst to etch a silicon substrate. Particularly, when a size of the opening part becomes a nano unit, it may be also used as a catalyst layer to form a silicon nanowire array by etching a silicon substrate.

According to a method for manufacturing a silicon nanowire array of the present invention, a porous metal film 40 is first prepared. A template having a plurality of holes on one side is provided in order to prepare the porous metal film 40 (FIG. 3, S310). The template 30 is a substrate having nano-sized holes 10 in constant intervals and shape of its cross section may be varied such as square, rectangular, regular polygon, round and oval, etc.

An anodizing method as an example may be used to form holes 10 on one side of the template 30. Anodizing is one of oxidations of the surface of aluminum in which while the aluminum is oxidized to the corresponding alumina, fine nano-sized holes are formed in constant intervals.

In particular, an anodizing process includes rinsing the surface of aluminum, performing pre-treatment of the aluminum by an electrolytic polishing in an electrolyte solution, and forming an oxide film by an oxidation on the surface of the aluminum by connecting the aluminum to a positive anode in an acid bath (sulfuric acid, oxalic acid, or phosphoric acid, etc.). A structure of such an oxide film is a nano-sized porous film and the area of the film converts the aluminum to alumina(Al₂O₃). Size shapes and intervals of holes may be controlled by adjusting anodizing periods, voltages, kinds of electrolytes and the like.

Then, a metal may be deposited on one side of the template 30 (FIG. 3, S320). The thin metal is deposited on one side of the template 30, except holes 10 of the template 30, to form a porous metal film 40 having opening parts 50. FIG. 4 illustrates the cross section of the porous metal film 40 formed on one side of the template 30 by depositing a metal.

According to an embodiment of the present invention, a porous multilayered metal film having the opening parts 50 may be formed by depositing a first metal thinly on one side of the template 30, except the holes 10 of the template 30, and then depositing a second metal thinly on the first metal.

A metal used in the present invention may be Au, Pt, or Ag, etc. that can be used as a catalyst during a chemical wet etching of a silicon substrate. When a porous multilayered metal film is prepared by using different metals, each metal deposited as the first metal and the second metal may act differently during the etching process due to the properties thereof.

If a metal depositing time is longer, size of the part 50 becomes smaller. Thus, the size of the opening part 50 may be controlled by adjusting the depositing time. The deposition may be performed by thermal evaporation, plasma sputter, or e-beam evaporation, etc. The porous metal film 40 may include a porous single layered metal film, porous multilayered metal film of 2 layers of different metals and a porous multilayered metal film of more than 2 layers of different metals.

The porous metal film 40 is then separated by removing the template 30 (FIG. 3, S340). The template 30 in contact with the porous metal film 40 is only etched by placing the template 30 in a template etching solution which does not etch the metal to leave the porous metal film 40. If the template is a porous alumina formed by the anodizing process, NaOH solution, KOH solution, H₃PO₄ solution or HF solution may be used as a template etching solution or the template may be floated on the surface of H₃PO₄ solution or HF solution to only etch and remove the template.

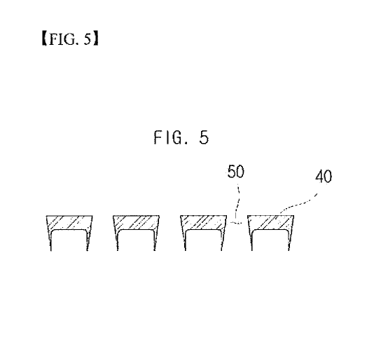

The parts where the porous metal film 40 is in contact with the template 30 may not be smooth or have bumps as shown in FIG. 5 because the metal is partially deposited on the wall of the holes of the template. Since when such bumps are formed, it may cause improper transferring to a silicon substrate 60, the surface may be polished for a short period of time (several seconds) by contacting it to a metal etching solution (for example, KI/I₂ solution for Au, HNO₃ solution for Ag) to remove the bumps(FIG. 3, S350).

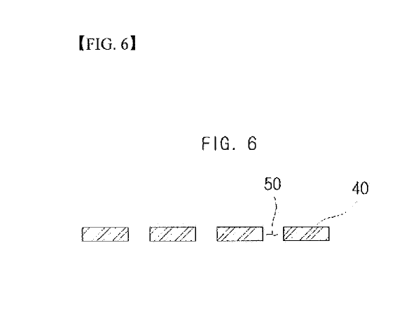

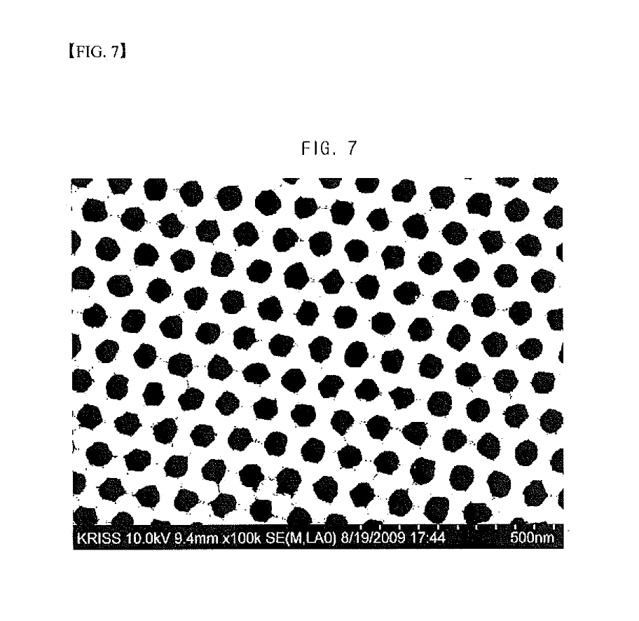

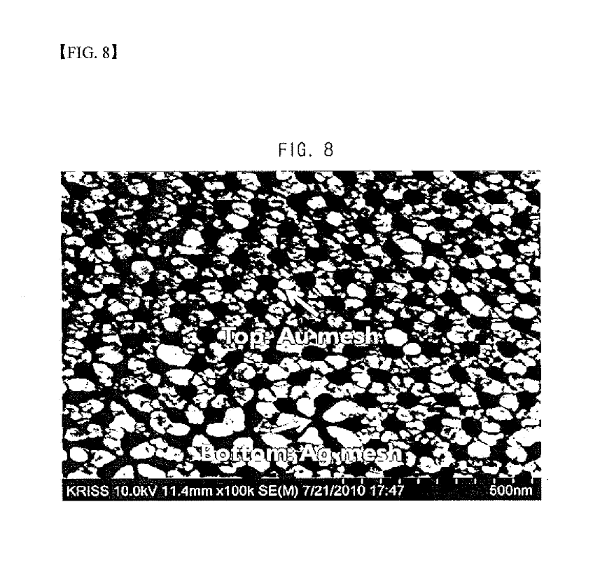

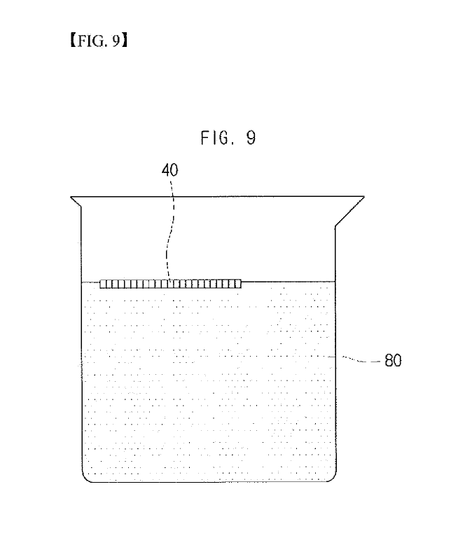

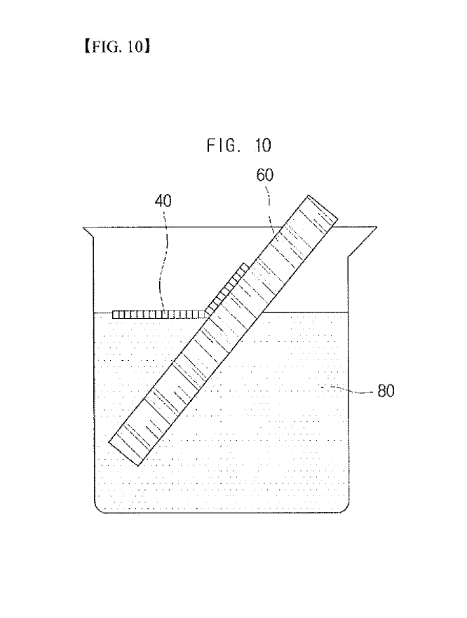

The cross section of the porous metal film 40 prepared through the polishing process is illustrated in FIG. 6, and FIG. 7 and FIG. 8 illustrate SEM images of a porous single layered metal film and a porous multilayered metal film, respectively. As described above, the porous metal film 40 having nano-sized uniform opening parts can be manufactured within a short period of time with a low manufacturing cost. Shapes of the opening parts may be varied with shapes of he holes of the template. The porous metal film 40 manufactured therefrom may be used as masks of various substrates.

A method for manufacturing a silicon nanowire array according to the present invention may include (a) preparing a porous metal film; (b) placing the porous metal film in contact with a silicon substrate; and (c) etching the silicon substrate with a silicon etching solution, and allow manufacturing silicon nanowires with controlled shapes and crystallographic orientations.

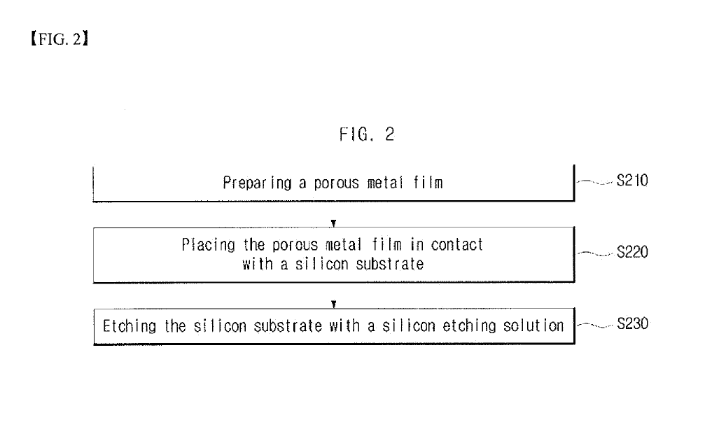

First, (a) a porous metal film may be prepared(FIG. 2, S210) by the method shown in FIG. 3. The detailed description is the same as described in the method for manufacturing the porous metal film above.

Then, (b) the porous metal film may be placed in contact with a silicon substrate(S220). The step of (b) may include floating the porous metal film on the surface of a carrier solution; placing one side of the porous metal film in contact with the surface of the carrier solution to contact with the silicon substrate; and evaporating the carrier solution remained on the silicon substrate.

One side of the porous metal film 40 in contact with the surface of the carrier solution may be contacted with one side of the silicon substrate 60 and immersed into a silicon etching solution to etch the silicon substrate by employing the porous single layered metal film as a catalyst to provide a vertically aligned large-area silicon nanowire array. Further, a vertically aligned large-area silicon nanowire array having strengths of the first metal and the second metal during the etching process may be manufactured when a porous multilayered metal film is used as a catalyst. According to the present invention, it is apparent that a porous multilayered metal film be used as the porous metal film 40.

Here, a silicon etching solution may be a composition including at least one of HF or NH₄F into a mixture of H₂O₂ and H₂O as a solution to etch the silicon by employing the porous metal film 40 as a catalyst.

A carrier solution 80 is a hydrophilic solution to transfer the porous metal film 40 to the silicon substrate 60 and thus, the porous metal film 40 having hydrophobicity can be floated on the surface of the carrier solution. The carrier solution 80 may be used as a silicon etching solution to etch the silicon later. Other solutions such as deionized water having hydrophilic property may be also used as the carrier solution 80 to make the porous metal film 40 float on the surface thereof,

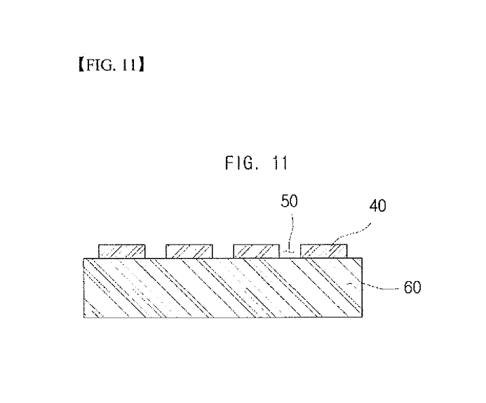

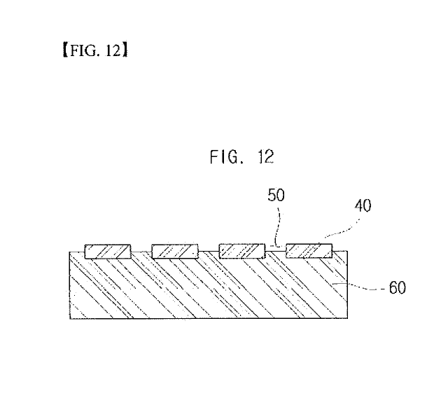

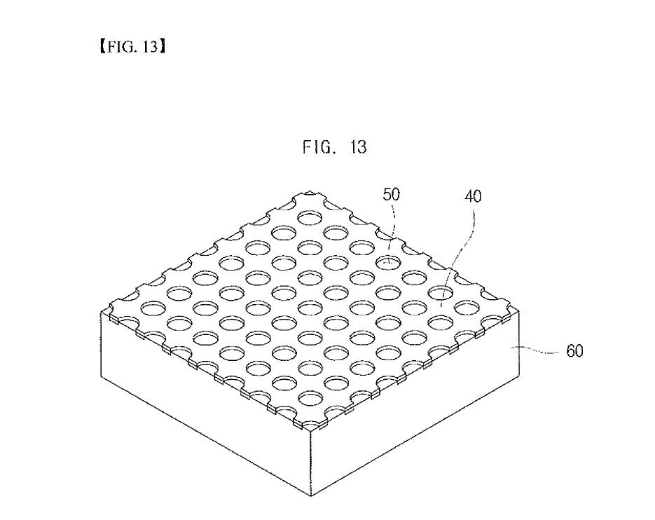

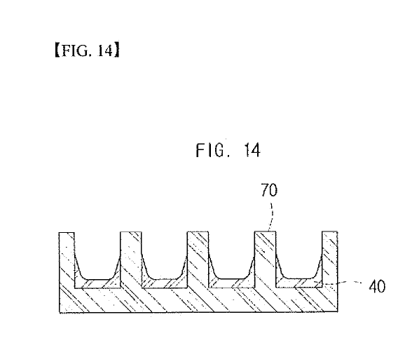

The silicon substrate 60 is immersed diagonally into the carrier solution 80 to transfer the porous metal film 40 floated on the surface of the carrier solution 80 to the silicon substrate 60. After the edge of the porous metal film 40 is contacted with the silicon substrate 60, the silicon substrate 60 is gradually lifted up, while maintaining an oblique angle from the carrier solution 80, to increase the contact area between the silicon substrate 60 and the porous metal film 40 so that the bottom part of the porous metal film 40 is gradually transferred to one side of the silicon substrate 60 as shown in FIG. 11.

Here, a step of evaporating the carrier solution remained on the silicon substrate 60 may be additionally performed. When the carrier solution 80 is a silicon etching solution, the silicon etching solution remained between the silicon substrate 60 and the porous metal film 40 may etch a part of the surface of the silicon substrate 60 while being dried and let the silicon substrate 60 be protruded through the opening parts 50 as the porous metal film 40 is sunk into the silicon substrate 60. This may be the upmost part of nanowires 70 and improve adhesion between the substrate and the porous metal film 40.

When the carrier solution 80 is deionized water, since a partial etching of the silicon substrate 60 may not occur during the step of evaporating the carrier solution remained on the silicon substrate 60, the adhesion between the silicon substrate 60 and the porous metal film 40 is not great but time to initiate a silicon etching to form nanowires may be shorter than that when the silicon etching solution is used as the carrier solution.

(c) The silicon substrate is then etched with the silicon etching solution (FIG. 2, S230). The silicon substrate 60 on which the porous metal film 40 is transferred may be immersed in the silicon etching solution and etched by employing the porous metal film 40 as a catalyst to provide a vertically aligned silicon nanowire array. Here, the silicon etching solution may be a mixture of HF, H₂O₂ and H₂O or a mixture of NH₄F, H₂O₂ and H₂O. Here, the porous metal film 40 may be remained on the silicon substrate since it acts as a catalyst and is not directly participated in the reaction.

When deionized water is used as the carrier solution, the separation of the porous metal film 40 from the silicon substrate 60 may be prevented by immersing the silicon substrate 60, on which the porous metal film 40 is transferred, into anhydrous ethanol(C₂H₅OH) before etching the silicon substrate 60. The surface of the silicon substrate 60 in contact with the porous metal film 40 may be selectively wet-etched by adding the silicon etching solution into anhydrous ethanol to provide a vertically aligned silicon nanowire array.

The wet etching of the silicon substrate using a metal as a catalyst will be described in detail. The metal in contact with the silicon substrate attracts electrons from the silicon in the etching solution. That is, Si is oxidized to SO⁴⁺ and a thin SiO₂ layer is formed at the interface between the metal and the silicon. The formed SiO₂ melts in acid and only silicon in contact with the metal is thus selectively melted, disappeared and etched with a series of successive cycles of such a process. Here, the metal only acts as a catalyst to attract electrons from the silicon to oxidize the silicon, instead of directly participating in the reaction.

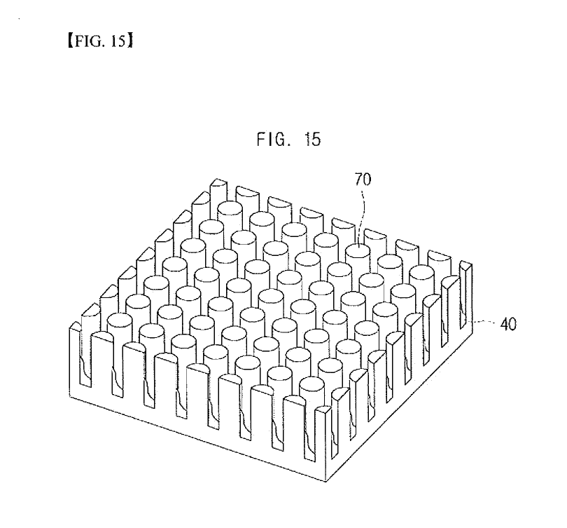

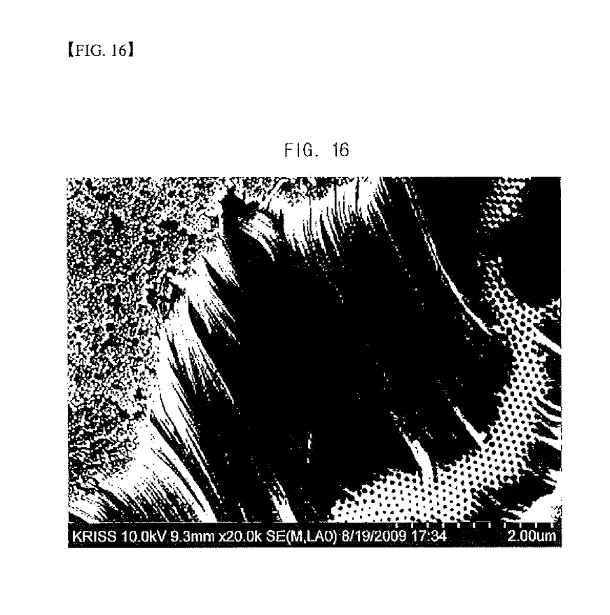

FIG. 15 is a perceptive view of a vertically aligned large-area silicon nanowire array. Since the shape of the nanowires 70 may vary with the shape of the opening parts 50 and thus may be controlled to various shapes such as round, oval, rectangular, square and regular polygon, etc. In addition, a length to diameter ratio of the silicon nanowires may be controlled by adjusting the etching time of the silicon substrate.

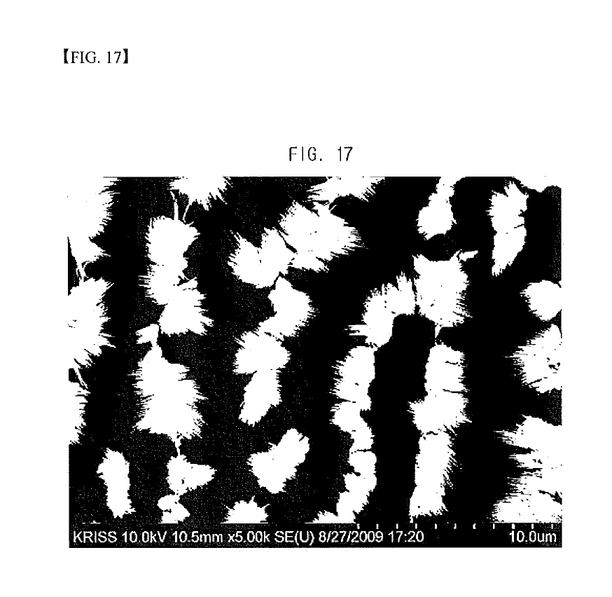

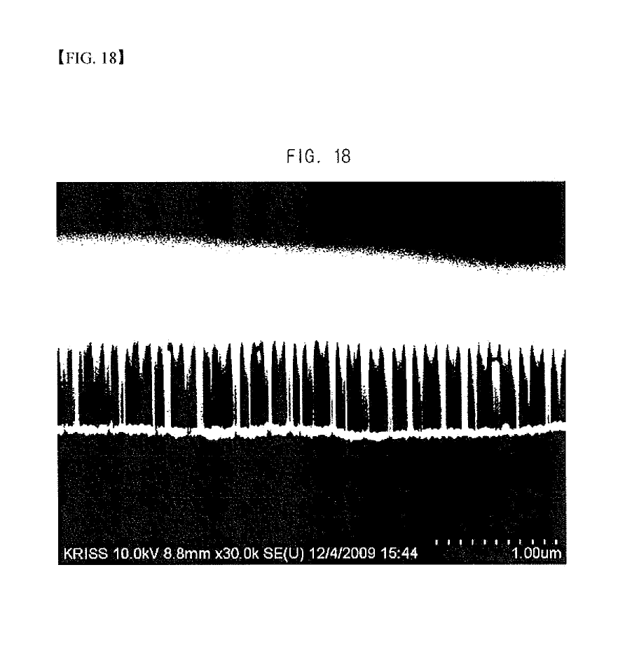

FIG. 17 and FIG. 18 each is a SEM image of a vertically aligned silicon nanowire array manufactured by the above-described method and it is toted that the nanowires are formed uniformly.

According to an aspect of the present invention, in the wet etching process of the silicon substrate 60 employing the porous metal film as a catalyst, various silicon nanowire arrays different in their shapes and crystallographic orientations, in addition to the vertically aligned silicon nanowire array, may be manufactured by adjusting the composition of the silicon etching solution and the etching temperature.

In the wet etching process of the silicon substrate 60 employing the porous metal film as a catalyst, the silicon etching solution is a mixture of HF, H₂O₂ and H₂O. Here, an excess amount of H₂O₂ may be added in the silicon etching solution by using a mixture having a volume ratio of HF:H₂O₂:H₂O=1:x:2 to provide the surface of a silicon nanowire array having a porous structure. Here, x is preferably 0.5 or more, more preferably from 0.5 to 1.

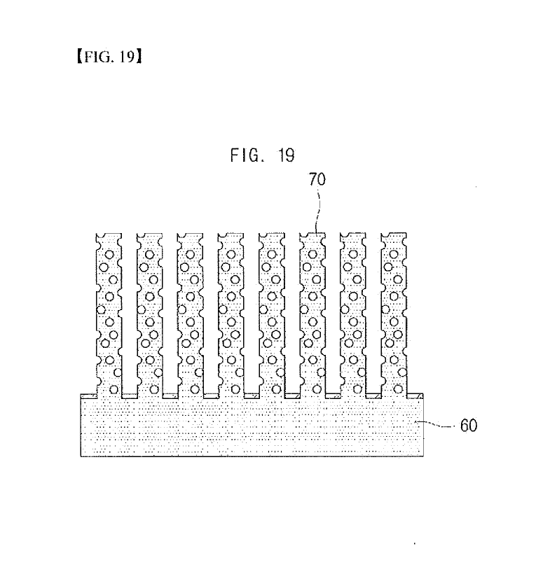

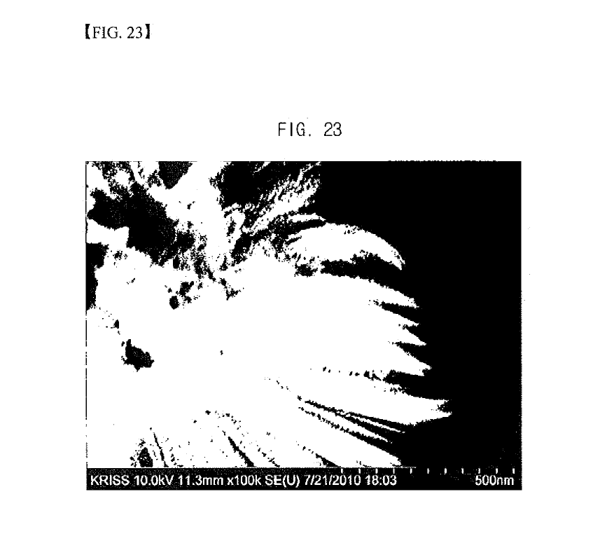

FIG. 19 is a sectional view illustrating a silicon nanowire array having a porous structure manufactured by the above method. FIG. 23 is a SEM image illustrating an embodiment of a silicon nanowire array having a porous structure manufactured by the above method. It is noted that the nanowires is formed in the porous structure.

In the wet etching process of the silicon substrate 60 employing the porous metal film as a catalyst, when a silicon nanowire array is manufactured by using a mixture of HF, H₂O₂ and H₂O as the silicon etching solution and then manufactured by using a mixture having a lowered concentration of HF in the mixture, it may provide a silicon nanowire array having a porous nodular structure by controlling to have a porous structure on the surface of the silicon nanowire array at the desired area.

Another method for manufacturing a silicon nanowire array having a porous nodular structure, in the wet etching process of the silicon substrate 60 employing the porous metal film as a catalyst, is to apply a voltage to the silicon substrate at the desired areas to have porous nodes by controlling to have a porous structure on the surface of the silicon nanowire array. The voltage applied to the desired area to have porous nodes is preferably 3V or higher, more preferably from 3V to 10V.

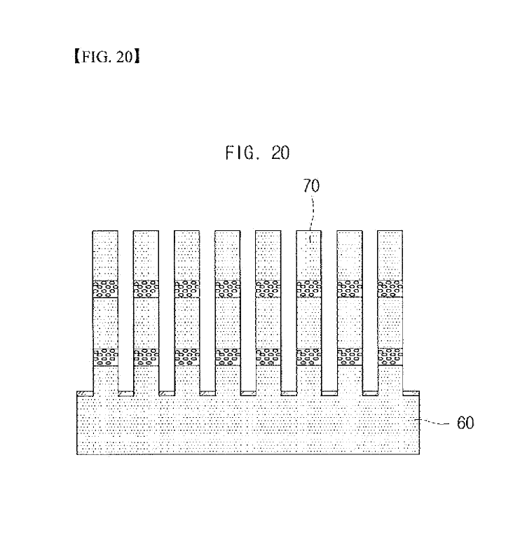

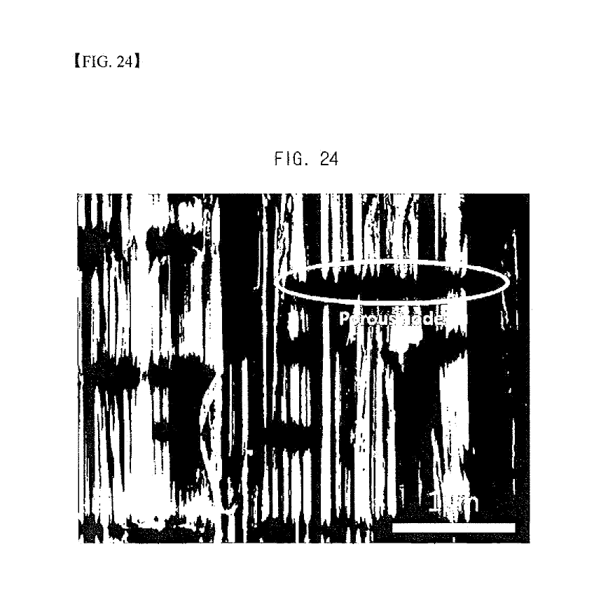

FIG. 20 is a sectional view illustrating a silicon nanowire array having a porous nodular structure manufactured by the above method and FIG. 24 is a SEM image illustrating an embodiment of a silicon nanowire array having a porous nodular structure manufactured by the above method. It is noted that the nanowires are formed in the porous nodular structure.

In the wet etching process of the silicon substrate 60 employing the porous metal film as a catalyst, a silicon nanowire array having an inclined structure may be manufactured by manufacturing the silicon nanowires not in the vertical direction, but in the inclined direction against the substrate using a heated silicon etching solution. The heating temperature of the silicon etching solution is preferably 50° C. or higher, more particularly from 50 to 70° C.

In addition, in the wet etching process of the silicon substrate 60 employing the porous metal film as a catalyst, a silicon nanowire array having an inclined structure in which axes of the nanowires are inclined against the substrate may be manufactured by using the silicon etching solution having a high concentration of H₂O₂ at a room temperature(25° C.).

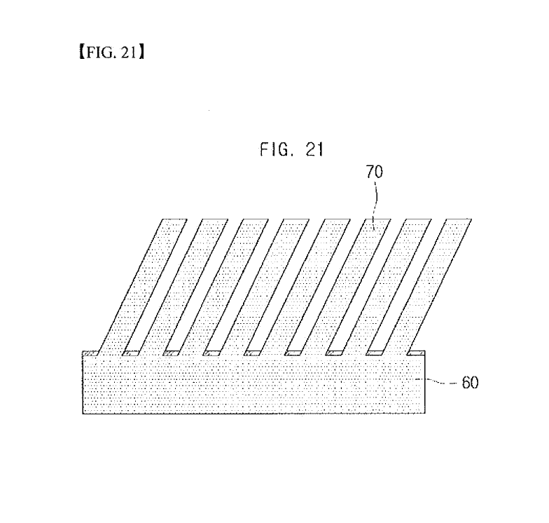

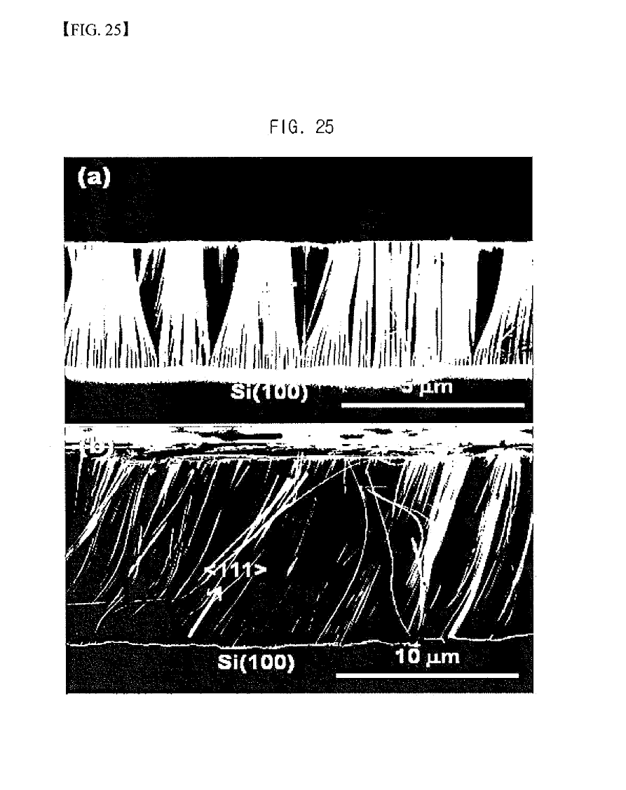

FIG. 21 is a sectional view illustrating a silicon nanowire array having an inclined structure in which axes of nanowires are inclined against the substrate manufactured by the above method and FIG. 25 is a SEM image of a silicon nanowire array having an inclined structure in which axes of nanowires are inclined against the substrate manufactured by the above method. It is noted that the axes of the nanowires are inclined against the substrate.

In the wet etching process of the silicon substrate 60 employing the porous metal film as a catalyst, a silicon nanowire array having a zig-zag structure may be manufactured by alternately etching in two etching solutions having different concentration of H₂O₂ functioning as an oxidizer in the silicon etching solution.

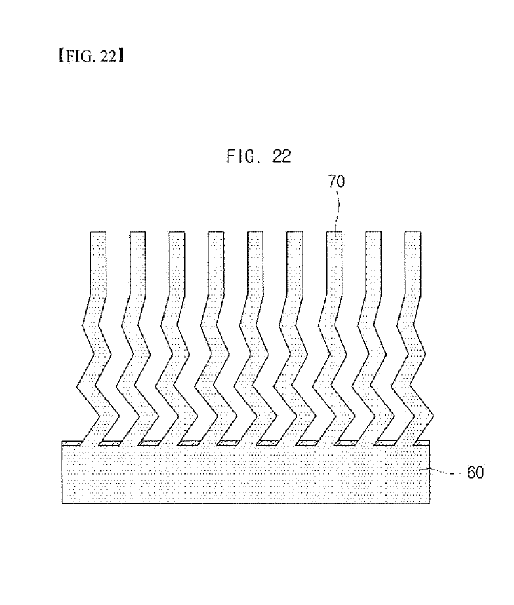

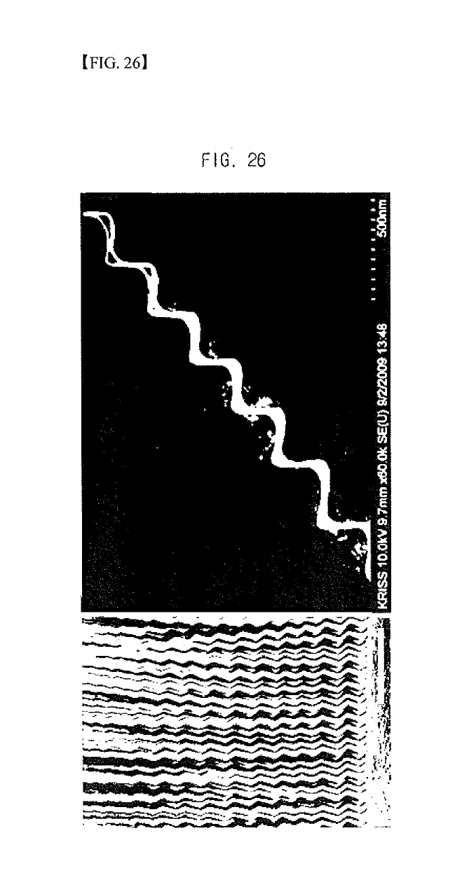

FIG. 22 is a sectional view illustrating a silicon nanowire array having a zig-zag structure manufactured by this method and FIG. 26 is a SEM image illustrating a silicon nanowire array having a zig-zag structure manufactured by this method. It is noted that the nanowires are formed in the zig-zag structure.

Hereinafter, although more detailed descriptions will be given by examples, those are only for explanation and there is no intention to limit the invention.

### EXAMPLE 1

### Preparation of a Porous Multilayered Metal Film

Pretreatment of Aluminum

Aluminum having a purity of 99.999% of the Goodfellow Corp. was washed with acetone to remove oil components existing on the surface of the aluminum. The degreased aluminum was electrolytic polished with a mixture mixed in a volume ratio of 1:4 of perchioric acid (HClO₄):ethyl alcohol at 30V as an electrolyte for 4 minutes to obtain the smooth surface of the aluminum like a mirror. Patterns having desired orientations and shapes were prepared on the electrolytic polished surface of the aluminum through the nanoimprint lithography using a stamp, if necessary.

Preparation of Nanoporous Alumina

The pre-treated aluminum was performed for an anodizing process by using sulfuric acid, oxalic acid, or phosphoric acid to prepare ordered nanoporous alumina.

TABLE 1

| | | | Distance | |
|---|---|---|---|---|
| | Voltage | Hole diameter | between holes | Hole density |
| electrolyte | (V) | (nm) | (nm) | (pores/cm³) |
| 0.3M H₂SO₄ | 25 | 18 | 60 | 3 × 10¹⁰ |
| 0.3M H₂C₂O₄ | 40 | 30 | 105 | 1 × 10¹⁰ |
| 0.3M H₂C₂O₄ | 120-140 | 40-50 | 240-280 | ~10⁹ |
| 1 wt. % H₃PO₄ | 195 | 180 | 500 | 5 × 10⁸ |

Deposition of Metal

A first metal chosen from Au, Pt and Ag, which can be used as a catalyst for the chemical wet etching of a silicon substrate, was deposited on the surface of the above-obtained nanoporous alumina and a second metal was then deposited thereon. The deposition of the first metal and the second metal was performed by at least one chosen from thermal evaporation, plasma sputter and e-beam evaporation. As the deposition time is longer, the diameter of the nanoporous alumina becomes smaller.

Preparation of a Porous Multilayered Metal Film

The nanoporous alumina deposited with multilayered metals on the surface thereof was floated on a NaOH solution, a mixture of HF, H₂O₂ and H₂O or a mixture of NH₄F, H₂O₂ and H₂O at room temperature to selectively remove only nanoporous alumina to obtain a large-area porous multilayered metal film.

A porous Ag/Au metal film having advantages of two metals of Ag and Au was manufactured by using Ag as the first metal which has a fast etching rate but causes the breaking of a structure during the etching process and Au as the second metal which has a slow etching rate but shows the solidity of a structure during the etching process.

When the silicon substrate was wet etched by using a porous Ag/Au metal film as a catalyst, not only silicon nanowires keep their structure, and the upper part and the bottom part of the silicon nanowires can have the same diameters due to strong mechanical properties of Au which can be obtained when an Au metal film is used as a catalyst for the etching of a silicon substrate, but also large-area silicon can be manufactured within a short period of time due to a fast etching rate obtained when an Ag metal film is used as a catalyst for the etching of a silicon substrate.

The porous Ag/Au metal film manufactured by the above method was transferred to the surface of a silicon substrate to be etched and the solution remained at the interface between the silicon substrate and the porous Ag/Au metal film was evaporated. When a solution to remove the nanoporous alumina was identical to the silicon etching solution, the silicon surface in contact with the porous Ag/Au metal film was etched during the evaporation of the solution, and thereby a part of the silicon nanowires was protruded as mesh of the porous Ag/Au metal film, resulting in physically adhering the silicon substrate and the porous Ag/Au metal film without separation each other during the etching process of the silicon.

On the other hands, when the nanoporous alumina was removed with a NaOH solution, the porous Ag/Au metal film floated on the NaOH solution was transferred to the surface of the deionized water by using a slide glass and the NaOH solution remained at the bottom part of the porous Ag/Au metal film was removed. After the porous Ag/Au metal film floated on the NaOH solution was transferred to the surface of the silicon substrate to be etched, the deionized water remained at the interface between the silicon substrate and the porous Ag/Au metal film was evaporated. A sample obtained prior to manufacture a silicon nanowire array by the etching process was immersed in an anhydrous ethanol.

### EXAMPLE 2

### Preparation of a Vertically Aligned Silicon Nanowire Array

The silicon substrate, which was placed on the surface of the porous metal film obtained in Example 1, was placed, immersed and etched in a mixture of HF, H₂O₂ and H₂O as a silicon etching solution to provide a vertically aligned silicon nanowire array.

### EXAMPLE 3

### Preparation of a Silicon Nanowire Array having a Porous Structure

The silicon substrate, which was placed on the surface of the porous metal film obtained in Example 1, was placed, immersed and etched in a mixture having a volume ratio of HF:H₂O₂:H₂O=1:x:2 as a silicon etching solution. Here, a porous structure was formed on the surface of a silicon nanowire array by using a mixture in which x is 0.7.

### EXAMPLE 4

### Preparation of a Silicon Nanowire Array having a Torous Nodular Structure

The silicon substrate, which was placed on the surface of the porous metal film obtained in Example 1, was placed, immersed and etched in a mixture having a volume ratio of HF:H₂O₂:H₂O=1:0.1:2 as a silicon etching solution. The silicon etching solution was then changed to a mixture having a volume ratio of HF:H₂O₂:H₂O=0.1:0.1:2 and the silicon substrate was further etched therein. A porous structure was formed at the areas etched with the mixture having a volume ratio of HF:H₂O₂:H₂O=0.1:0.1:2 while the process was repeated.

The silicon substrate, which was placed on the surface of the porous metal film obtained in Example 1, was placed, immersed and etched in a mixture having a volume ratio of HF:H₂O₂:H₂O=1:0.1:2 as a silicon etching solution. Here, when voltage of 5V was applied to the silicon substrate, a porous structure was formed on the surface of the silicon nanowire array of the areas where the voltage was applied.

### EXAMPLE 5

### Preparation of a Silicon Nanowire Array having an Inclined Structure in Which Axes of Nanowires are Inclined Against a Substrate

A mixture having a volume ratio of HF:H₂O₂:H₂O=1:0.1:0.1 as a silicon etching solution was heated to 60° C. The silicon substrate, which was placed on the surface of the porous metal film obtained in Example 1, was placed, immersed and etched in the mixture to provide silicon nanowires having an inclined structure in which axes of the nanowires are inclined against the substrate.

### EXAMPLE 6

### Preparation of a Silicon Nanowire Array having a Zigzag Structure

The silicon substrate, which was placed on the surface of the porous metal film obtained in Example 1, was placed, immersed and etched in a mixture having a volume ratio of HF:H₂O₂:H₂O=1:0.01:2 as a silicon etching solution. The silicon etching solution was then changed to a mixture having a volume ratio of HF:H₂O₂:H₂O=1:0.1:2 and further the silicon substrate was etched. A silicon nanowire array having a zig-zag structure was manufactured by repeating the process.

As such, many embodiments other than that set forth above can be found in the appended claims.

1. A method for manufacturing a silicon nanowire array comprising:
(a) preparing a porous metal film;
(b) placing the porous metal film in contact with a silicon substrate; and
(c) etching the silicon substrate with a silicon etching solution.

2. The method for manufacturing a silicon nanowire array of claim 1, wherein the step (a) of preparing a porous metal film comprises:
providing a template having a polarity of holes on one side;
depositing a metal on one side of the template; and
etching only the template with a template etching solution.

3. The method for manufacturing a silicon nanowire array of claim 1, wherein the porous metal film is formed with a multilayer of 2 or more layers composed of different metals.

4. The method for manufacturing a silicon nanowire array of claim 2, wherein the cross section of the hole of the one side of the template has shape selected from the group consisting of round, oval, square, rectangular and regular polygon.

5. The method for manufacturing a silicon nanowire array of claim 2, wherein material of the template is alumina and the hole of the one side of the template is formed by an anodizing method.

6. The method for manufacturing a silicon nanowire array of claim 2, further comprising polishing the surface of the porous metal film to make the surface of the porous metal film be smooth after etching only the template.

7. The method for manufacturing a silicon nanowire array of claim 1, wherein the step of placing the porous metal film in contact with a silicon substrate comprises
floating the porous metal film on the surface of a carrier solution;
placing one side of the porous metal film in contact with the surface of the carrier solution to contact with the silicon substrate ; and
evaporating the carrier solution remained on the silicon substrate.

8. The method for manufacturing a silicon nanowire array of claim 7, wherein the carrier solution is the silicon etching solution and the step of evaporating the carrier solution remained on the silicon substrate etches a part of the silicon substrate at the area in contact with the porous metal film with the carrier solution and adhering the porous metal film and the silicon substrate.

9. The method for manufacturing a silicon nanowire array of claim 7, wherein the carrier solution is deionized water and the method further comprises immersing the silicon substrate in contact with the porous metal film in an anhydrous ethanol(C₂H₅OH) after the step of evaporating the carrier solution remained on the silicon substrate.

10. The method for manufacturing a silicon nanowire array of claim 1, wherein at the step of (c), the porous metal film acts as a catalyst in the silicon etching solution to form nanowires by a wet etching method,

11. The method for manufacturing a silicon nanowire array of claim 1, wherein the silicon etching solution is a mixture of HF, H₂O₂ and H₂O or a mixture of NH₄F, H₂O₂ and H₂O.

12. The method for manufacturing a silicon nanowire array of claim wherein in the step of (c), the silicon etching solution is a mixture of HF, H₂O₂ and H₂O having a volume ratio of HF:H₂O₂:H₂O=1:x:2(wherein x is 0.5 or higher) to form the silicon nanowires having a porous structure.

13. The method for manufacturing a silicon nanowire array of claim 1, wherein in the step of (c),
the silicon etching solution is a mixture of HF, H₂O₂ and H₂O; and
after etching with the mixture, an additional etching is performed with a mixture having a lowered concentration of HF in the mixture to form the silicon nanowires having a porous nodular structure.

14. The method for manufacturing a silicon nanowire array of claim 1, wherein in the step of (c),
when a voltage is applied to the silicon substrate, the area of the silicon nanowires where the voltage is applied has a porous structure to form silicon nanowires having a porous nodular structure.

15. The method for manufacturing a silicon nanowire array of claim 1, wherein in the step of (c),
axes of the silicon nanowires forms an inclined structure against the surface of the substrate by using a heated silicon etching solution.

16. The method for manufacturing a silicon nanowire array of claim 1, wherein in the step of (c),
silicon nanowires having a zig-zag structure is formed by alternately etching with the silicon etching solution having different concentrations of H₂O₂.

17. A silicon nanowire array manufactured by the method according to claim 16.

18. A semiconductor device comprising the silicon nanowire array of claim 17.
